(19) United States
(12) Patent Application Publication
(10) Pub. No.: US 2011/0057326 A1
(43) Pub. Date: Mar. 10, 2011

(54) METHOD FOR FORMING THROUGH ELECTRODE AND SEMICONDUCTOR DEVICE

(76) Inventors: Takayuki Kai, Kyoto (JP); Kazushi Higashi, Osaka (JP); Takeshi Kita, Hyogo (JP); Hitoshi Yamanishi, Osaka (JP); Takafumi Okuma, Osaka (JP)

(21) Appl. No.: 12/991,720

(22) PCT Filed: Dec. 1, 2009
(86) PCT No.: PCT/JP2009/006505

§ 371 Date: Nov. 9, 2010

(30) Foreign Application Priority Data
Dec. 17, 2008 (JP) 2008-321042

(51) Int. Cl. H01L 23/48; H01L 21/768

(52) U.S. Cl. 257/774; 438/667; 257/E21.597; 257/E23.011

(57) ABSTRACT

An electrode on a first surface of a semiconductor substrate and a second surface of the semiconductor substrate are connected with each other by a through electrode. A through hole is formed through the semiconductor substrate from the second surface of the semiconductor substrate to an interlayer insulating film on the first surface, and an insulating film is formed on a side surface and a bottom surface of the through hole as well as on the second surface of the semiconductor substrate, so that by simultaneously etching the insulating film on the bottom surface of the through hole and the interlayer insulating film, thus formed, the through hole is formed so as to reach the electrode on the first surface of the semiconductor substrate.

### TECHNICAL FIELD

The present invention relates to a semiconductor device in which an electronic circuit including an active element is formed on a first surface of a semiconductor substrate and an electrode on the first surface thereof and a conductive layer on a second surface of the semiconductor substrate are electrically connected to each other by a through electrode that penetrates the semiconductor substrate. The present invention also concerns a method for forming such a through electrode and a semiconductor device having the semiconductor substrate provided with the through electrode.

### RELATED ART

In order to reduce the package area of an integrated circuit, a through electrode 103 that penetrates a semiconductor substrate 101 has been used in place of conventional wire bonding (for example, see FIG. 5 of Patent Document 1). FIGS. 17 to 19G are a structural view showing the through electrode 103 that penetrates a conventional semiconductor substrate 101, a forming flow chart, and a process view, respectively.

Referring to FIGS. 17 to 19G, the following description will discuss a method for manufacturing the conventional semiconductor substrate 101.

After having formed an active element 107 (see FIG. 20) such as a transistor on a first surface 101a of the semiconductor substrate 101, a pad electrode 105 is formed inside an interlayer insulating film 102. Moreover, in order to electrically connect the pad electrode 105 inside the interlayer insulating film 102 through a second surface 101b of the semiconductor substrate 101, the through electrode 103 is formed by using a flow chart shown in FIG. 18. In this case, the pad electrode 105 of FIG. 17 and the active element 107 of FIG. 20 are located on the same surface 101a of the semiconductor substrate 101. The thickness of the interlayer insulating film 102 is set to 1 μm, and aluminum (thickness: 800 nm) is used as the material for the pad electrode 105, while three layers of titanium nitride and titanium (thickness: 200 nm in combination with titanium nitride and titanium) are used as close contact layers. In this case, with respect to the close contact layer, only titanium nitride with a thickness of 150 nm may be used, or only titanium with a thickness of 150 nm may be used, or titanium nitride and titanium with a combined thickness of 150 nm may be used. A silicon nitride film having a thickness of 1 μm is formed on the surface of the pad electrode 105 as a passivation film 108. Moreover, silicon doped into a p-type is used as the semiconductor substrate 101, with the thickness thereof being reduced by a grinder (FIG. 21). In the conventional technique, the thickness of the silicon semiconductor substrate 101 is reduced to 200 μm. The size of the pad electrode 105 is 150 μm×150 μm. Moreover, as shown in FIGS. 20 and 21, the surface of the silicon semiconductor substrate 101 on the active element 107 side is covered with a carrier substrate 120 so that the active element 107 and the other electrodes are protected by the carrier substrate 120. Glass is used as the carrier substrate 120.

Referring to a flow chart shown in FIG. 18, the following description will discuss a method for forming the through electrode 103.

First, as shown in FIG. 19A, a through hole 106 is formed through the semiconductor substrate 101 by etching in an eleventh process. In this case, the pad electrode 105 (metal electrode) is placed on the surface 101a of the semiconductor substrate 101 on which the active element 107 (see FIG. 20) is disposed. Moreover, between the pad electrode 105 and the semiconductor substrate 101, the interlayer insulating film 102 is placed, and a resist mask 130 having a thickness of 30 μm is formed on the surface 101b on the side opposite to the semiconductor substrate 101 at portions other than the through electrode formation portion 101c.

Next, as shown in FIG. 19B, the portion that is not covered with the resist mask 130 of the surface 101b on the opposite side of the semiconductor substrate 101, that is, the through electrode formation portion 101c of the semiconductor substrate 101 is etched by dry etching down to the interlayer insulating film 102 so that a through hole 106 is formed. For example, the thickness of the silicon semiconductor substrate 101 of FIG. 17 is 200 μm, the diameter of the inlet of the through hole 106 is 100 μm, and the through hole 106 has a tapered shape having an angle of 89°.

Next, as shown in FIG. 19C, after the etching process, all the resist mask 130 is removed from the surface 101b on the opposite side of the semiconductor 101 by using an asking process.

Thereafter, as shown in FIG. 19D, in a twelfth process, all the portion having a thickness of 1 μm of the interlayer insulating film 102 on a bottom surface of the through hole 106 is removed by dry etching so that titanium on the lower surface side of the pad electrode 105 is exposed to the bottom surface of the through hole 106.

Next, as shown in FIG. 19E, in a thirteenth process, an insulating film 104 is formed by a CVD method on the bottom surface and a side surface of the through hole 106, as well as on the surface (surface 101b on the opposite side of the semiconductor substrate 101) on the opening side of the through hole 106 of the semiconductor substrate 101. The thickness of the insulating film 104 on the surface on the opening side of the through hole 106 is 2 μm, and the thickness of the insulating film 104 on the bottom surface of the through hole 106 is 0.2 μm. With respect to the thickness of the insulating film 104 on the side surface of the through hole 106, the thickness of the insulating film 104 adhered to the side surface near the surface 101b of the through hole 106 is substantially equal to the thickness of the insulating film 104 of the surface 101b on the opposite side of the semiconductor substrate 101, and is gradually reduced from the surface 101b side of the through hole 106 toward the bottom side thereof, with the result that the thickness of the insulating film 104 adhered to the side surface near the bottom surface of the through hole 106 is made substantially the same as the thickness of the insulating film 104 adhered to the bottom surface of the through hole 106. Additionally, FIG. 19D is a schematic view so that the respective dimensions are illustrated in a different manner from those of the explanation.

Next, as shown in FIG. 19F, in a fourteenth process, in order to prevent the insulating film 104 on the side surface of the through hole 106 from being etched, the portion of the insulating film 104 corresponding to a thickness of 0.5 μm on the bottom surface of the through hole 106 and one portion of the insulating film 104 of the surface 101b on the opening side of the through hole 106 of the semiconductor substrate 101 are removed by dry etching so that titanium on the lower surface side of the pad electrode 105 is again exposed to the bottom surface of the thorough hole 106.

Next, in a fifteenth process, a metal film 131 is deposited on the inside of the through hole 106 by a sputtering method so that a seed layer for use in plating in a sixteenth process is formed. As the conventional technique, copper is used as an electrode material for the metal film of the through electrode 103. Moreover, titanium is used as the close contact layer. The thickness of titanium to be deposited on the bottom surface of the through hole 106 is about 50 nm. Moreover, titanium for use in the close contact layer is formed on the side surface and bottom surface of the through hole 106, as well as on the surface 101b of the semiconductor substrate 101 on the through hole 106 side.

Next, in a sixteen process, by allowing an electric current to flow through the titanium and copper, an electrolytic plating process of copper is carried out so that copper is grown on the inside and the surface 101b of the through hole 106, and thus the metal layer 131 is made further thicker to form the through electrode 103.

Next, although not specifically illustrated, in a seventeenth process, an electrode wiring pattern is formed through a formation of a resist mask and an etching process, and the resist mask is then removed.

As shown in FIG. 22, in the last process, a dividing process into individual pieces is carried as shown in FIG. 17.

Moreover, in examples of Patent Document 1 and Patent Document 2, after the etching process of the through hole, electrodes are respectively formed on both of the surfaces of the semiconductor substrate 101.

As a method for forming the through electrode so as to draw the pad electrode on the surface of the silicon substrate onto the rear surface of the silicon substrate, Patent Document 3 has proposed one example. In the example of Patent Document 3, a through hole with the pad electrode forming its bottom surface is formed by etching the silicon substrate and the interlayer insulating film from the rear surface of the silicon substrate, and an insulating film is formed on the side wall made of the silicon substrate of this through hole and on the rear surface of the silicon substrate, and a metal material, such as copper, is then formed on the insulating film in a manner so as to fill the through hole, with this metal material being shaped into a predetermined shape so as to form an electrode.

Moreover, as a method for forming the through electrode so as to draw the pad electrode on the surface of the semiconductor substrate onto the rear surface of the semiconductor substrate, Patent Document 4 has proposed one example. In the example of Patent Document 4, one portion of a first insulating film on the surface of the semiconductor substrate is etched to form an opening section, and after a pad electrode has been formed from the inside of the opening section, a second insulating film is formed. Moreover, a via-hole having an opening diameter larger than the opening section is formed, and a third insulating film that extends from the inside of the via-hole onto the second insulating film is formed so that by etching the third insulating film on the bottom portion of the via-hole, the pad electrode is exposed to form a through electrode and a wiring layer inside the via-hole.

### PRIOR-ART DOCUMENTS

### Patent Document

Patent Document 1: JP-A No. 2006-114568

Patent Document 2: JP-A No. 2004-95849

Patent Document 3: JP-A No. 2005-093486

Patent Document 4: JP-A No. 2006-032699

### DISCLOSURE OF INVENTION

### Summary of the Invention

According to an aspect of the present invention, there is provided a method for forming a through electrode, in which an interlayer insulating film is formed on a first surface of a semiconductor substrate; an electronic circuit including an active element is disposed on the interlayer insulating film; and an electrode that is connected to the electronic circuit and formed on the first surface thereof, and a conductive layer formed on a second surface of the semiconductor substrate, are connected by using the through electrode, the method comprising:

forming a through hole through the semiconductor substrate, which passes toward the electrode from the second surface to the interlayer insulating film;

forming an insulating film on a side surface and a bottom surface of the through hole as well as on the second surface;

etching the insulating film formed on the bottom surface and the interlayer insulating film on the electrode so that a surface of the electrode on a first surface side is exposed; and

forming a metal layer on each of the second surface of the semiconductor substrate and the side surface and the bottom surface of the through hole so that the through electrode is formed, with the electrode exposed and the metal layer being connected with each other by the through electrode.

According to an another aspect of the present invention, there is provided a semiconductor device, in which: an interlayer insulating film is formed on a first surface of a semiconductor substrate; an electronic circuit including an active element is arranged on the interlayer insulating film; and an electrode that is connected to the electronic circuit and formed on a first surface thereof, and a conductive layer formed on the second surface of the semiconductor substrate, are connected by using the through electrode, the device characterized by further comprising:

an insulating film that is placed between the through electrode and the semiconductor substrate as well as inside the through hole, so as to insulate between the through electrode and the semiconductor substrate; and

an interlayer insulating film that is placed on the first surface to insulate the electrode and the semiconductor substrate from each other, and is made in contact with the through electrode.

### BRIEF DESCRIPTION OF DRAWINGS

These and other aspects and features of the present invention will become clear from the following description taken in conjunction with the preferred embodiments thereof with reference to the accompanying drawings, in which:

FIG. 1 is a schematic enlarged cross-sectional view of a semiconductor substrate showing a neighboring portion of a through electrode formed by using a method for forming the through electrode in accordance with an embodiment of the present invention;

FIG. 2 is a flow chart showing the method for forming a through electrode in accordance with the embodiment of the present invention;

FIG. 3 is a schematic view showing a semiconductor device using the through electrode formed by using the method for forming a through electrode in accordance with the embodiment of the present invention;

FIG. 4A is a view showing a process of the method for forming a through electrode in accordance with the embodiment of the present invention;

FIG. 4B is a view showing a process of the method for forming a through electrode that follow FIG. 4A in accordance with the embodiment of the present invention;

FIG. 4C is a view showing a process of the method for forming a through electrode that follow FIG. 4B in accordance with the embodiment of the present invention;

FIG. 4D is a view showing a process of the method for forming a through electrode that follow FIG. 4C in accordance with the embodiment of the present invention;

FIG. 4E is a view showing a process of the method for forming a through electrode that follow FIG. 4D in accordance with the embodiment of the present invention;

FIG. 4F is a view showing a process of the method for forming a through electrode that follow FIG. 4E in accordance with the embodiment of the present invention;

FIG. 4G is a view showing a process of the method for forming a through electrode that follow FIG. 4F in accordance with the embodiment of the present invention;

FIG. 4H is a view showing a process of the method for forming a through electrode that follow FIG. 4G in accordance with the embodiment of the present invention;

FIG. 4I is a view showing a process of the method for forming a through electrode that follow FIG. 4H in accordance with the embodiment of the present invention;

FIG. 4J is a view showing a process of the method for forming a through electrode that follow FIG. 4I in accordance with the embodiment of the present invention;

FIG. 4K is a view showing a process of the method for forming a through electrode that follow FIG. 4J in accordance with the embodiment of the present invention;

FIG. 5A is a schematic cross-sectional view showing a through hole at the time when an insulating film inside the through hole is processed by a dry etching process of the method for forming a through electrode in accordance with the embodiment of the present invention;

FIG. 5B is a schematic cross-sectional view showing a through hole at the time when the insulating film inside the through hole is processed by the dry etching process of the method for forming a through electrode in accordance with the embodiment of the present invention;

FIG. 6 is a schematic cross-sectional view that shows a dry etching device used for processing the insulating film of the through hole in the dry etching process of the method for forming a through electrode in accordance with the embodiment of the present invention;

FIG. 7 is a graph that shows a pressure dependence of the ratio between an etching rate of an insulating film of a second surface of a semiconductor substrate and an etching rate of an insulating film of a bottom surface inside a through hole in a third process of the method for forming a through electrode in accordance with the embodiment of the present invention;

FIG. 8 is a graph that shows a pressure dependence of a thickness required for an insulating film to be deposited on the second surface of the semiconductor substrate in a second process of the method for forming a through electrode in accordance with the embodiment of the present invention;

FIG. 9 is a graph that shows a pressure dependence of etching-speed uniformity required for ensuring a thickness of a remaining insulating film on the second surface of the semiconductor substrate in the second and third processes of the method for forming a through electrode in accordance with the embodiment of the present invention;

FIG. 10 is a cross-sectional view that explains a process for bonding a carrier substrate to the semiconductor substrate made by the method for forming a through electrode in accordance with the embodiment of the present invention;

FIG. 11, which follows FIG. 10, is a cross-sectional view that explains a reducing process for thickness of the semiconductor substrate;

FIG. 12, which follows FIG. 11, is a cross-sectional view that explains a state prior to a manufacturing process of the semiconductor device in which the semiconductor substrate is divided into individual pieces and used for the semiconductor device;

FIG. 13, which is a cross-sectional view that shows a through electrode forming process by using a conventional method, and is a cross-sectional view that shows a shape of a through hole in the case where an etching speed inside the through hole is low upon processing an insulating film inside the through hole in a dry etching process;

FIG. 14A is an enlarged cross-sectional view showing a neighboring portion of a pad electrode of a through electrode, which explains a state in which, upon forming the through electrode by the conventional method, a silicon semiconductor substrate and the electrode are connected with each other to generate a leak current;

FIG. 14B is an enlarged cross-sectional view showing a neighboring portion of a pad electrode, which explains a state in which, upon forming the through electrode by using the method of forming a through electrode in accordance with the embodiment of the present invention, a silicon semiconductor substrate and the electrode are not connected with each other so that the occurrence of a leak current is prevented;

FIG. 15A is a cross-sectional view showing the neighboring portion of the pad electrode of the through electrode in a further enlarged manner, which explains a state in which, in FIG. 14A showing the conventional method, a strain occurs due to a temperature rise during an operation of the semiconductor device to cause a rupture in the insulating film;

FIG. 15B is a cross-sectional view showing the neighboring portion of the pad electrode of the through electrode in a further enlarged manner, which explains a state in which a leak current is generated in the conventional method of FIG. 14A;

FIG. 16A is a cross-sectional view showing the neighboring portion of the pad electrode of the through electrode in a further enlarged manner, which explains a state in which, by using the embodiment of the present invention of FIG. 14B, no strain occurs even under a temperature rise during an operation of the semiconductor device so that it is possible to prevent a rupture in the insulating film;

FIG. 16B is a cross-sectional view showing the neighboring portion of the pad electrode of the through electrode in a further enlarged manner, which explains that by using the embodiment of the present invention of FIG. 14B, it is possible to prevent an occurrence of a leak current;

FIG. 17 is a schematic enlarged cross-sectional view showing a semiconductor device near the through electrode made by the conventional method of forming the through electrode;

FIG. 18 is a flow chart showing a method for forming the conventional through electrode;

FIG. 19A is a process view showing the method for forming the conventional through electrode;

FIG. 19B, which follows FIG. 19A, is a process view showing the method for forming the conventional through electrode;

FIG. 19C, which follows FIG. 19B, is a process view showing the method for forming the conventional through electrode;

FIG. 19D, which follows FIG. 19C, is a process view showing the method for forming the conventional through electrode;

FIG. 19E, which follows FIG. 19D, is a process view showing the method for forming the conventional through electrode;

FIG. 19F, which follows FIG. 19E, is a process view showing the method for forming the conventional through electrode;

FIG. 19G, which follows FIG. 19F, is a process view showing the method for forming the conventional through electrode;

FIG. 20 is a cross-sectional view that explains processes for bonding a carrier substrate to the semiconductor substrate having a through hole made by the conventional method for forming a through electrode;

FIG. 21, which follows FIG. 20, is a cross-sectional view that explains a reducing process for the thickness of the semiconductor substrate; and

FIG. 22, which follows FIG. 21, is a cross-sectional view that explains a state prior to a manufacturing process of the semiconductor device in which the semiconductor substrate is divided into individual pieces and used for the semiconductor device.

### DESCRIPTION OF EMBODIMENTS

Before the description of the present invention proceeds, it is to be noted that like parts are designated by like reference numerals throughout the accompanying drawings.

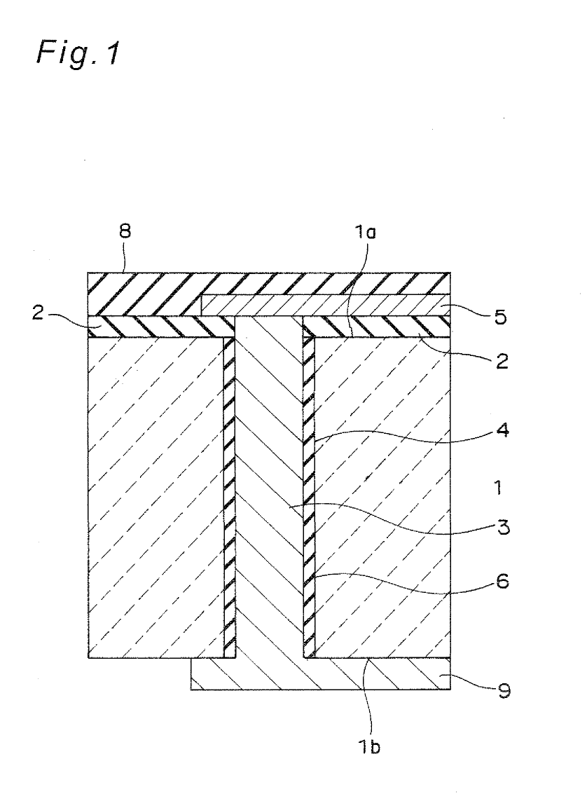

Referring to FIGS. 1 to 16B, the following description will discuss a method for forming a through electrode 3 in accordance with the embodiments of the present invention.

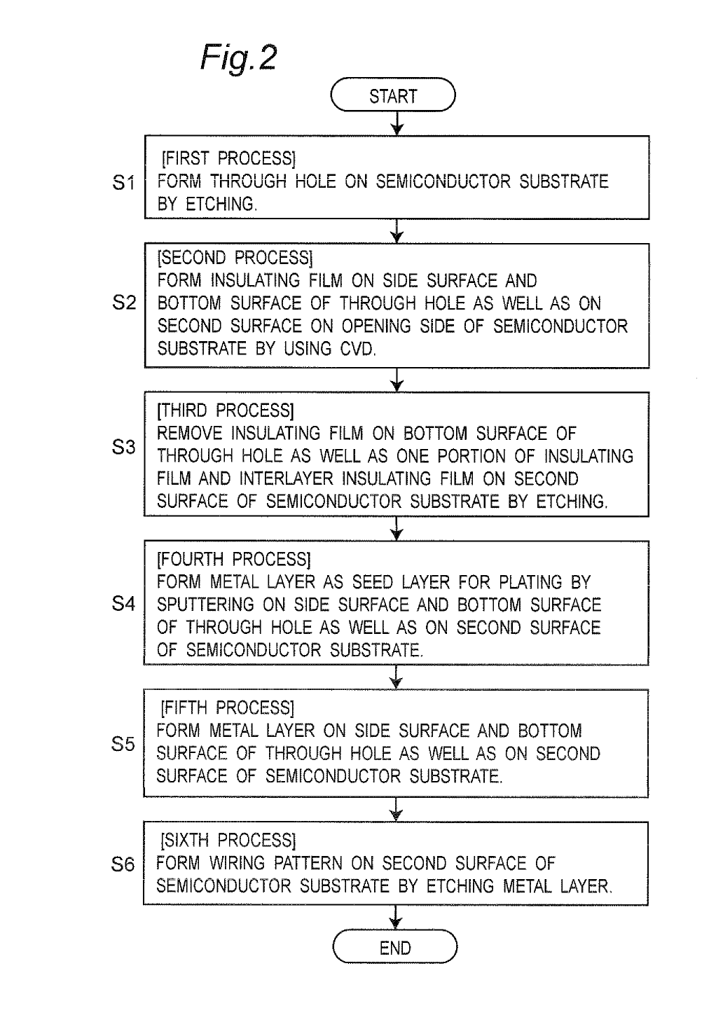

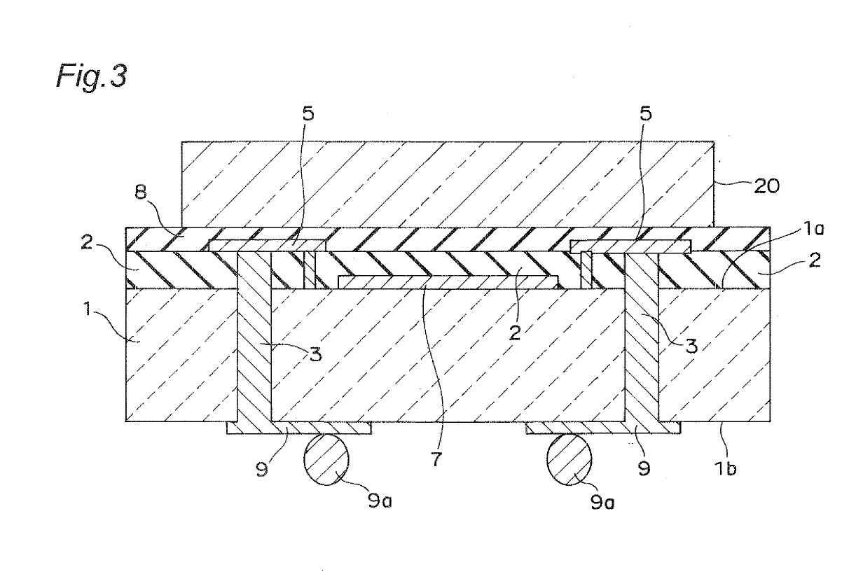

FIG. 1 is a schematic cross-sectional view of a semiconductor substrate showing a neighboring portion of a through electrode 3 formed by using a method for forming the through electrode 3 in accordance with an embodiment of the present invention. FIG. 2 is a flow chart showing the forming processes of the through electrode 3 made by the method for forming the through electrode 3 in accordance with the embodiment of the present invention. Moreover, FIG. 3 is a schematic view showing a semiconductor device using the through electrode 3 that penetrates a semiconductor 1.

For example, the structure of an active element 7 side of the semiconductor substrate 1 is the same as that explained in the background art; however, the present invention is not intended to be limited thereby.

After an electronic circuit including an active element 7 such as a transistor has been formed on a first surface 1a of the semiconductor substrate 1 (see FIG. 3), a pad (PAD) electrode 5 is formed in an interlayer insulating film 2. Moreover, in order to electrically connect a conductive layer 32a of a second surface 1b of the semiconductor substrate 1 with the pad electrode 5 inside the interlayer insulating film 2 of the first surface 1a of the semiconductor substrate 1 from the second surface 1b of the semiconductor substrate 1, the through electrode 3 is formed in a manner so as to penetrate the semiconductor substrate 1 and one portion of the interlayer insulating film 2 by using processes as shown in a flow chart of FIG. 2. More specifically, as described in detail below, the through electrode 3 is made of a conductor such as a metal layer, which is continuously formed on an insulating film 4 that entirely covers the inner surface of a through hole 6 that penetrates the semiconductor substrate 1 from the second surface 1b to the first surface 1a, as well as on the inner side of the through hole 6a of the interlayer insulating film 2 from the first surface 1a of the semiconductor substrate 1 to the electrode 5. Therefore, the through electrode 3 is insulated from the semiconductor substrate 1 by the insulating film 4, and is also insulated from the semiconductor substrate 1 by the interlayer insulating film 2 outside the first surface 1a of the semiconductor substrate 1.

For example, the material for the pad electrode 5 is aluminum or titanium, and may be prepared as a conductor, such as polysilicon, tungsten, tantalum, titanium nitride, tantalum nitride, gold, silver, or the like.

The interlayer insulating film 2 is made of at least one or more kinds of insulating films, and may be made of a combination of an element-separation thermal oxide film, silicon nitride, non-doped silicon glass, BP-doped silicon glass, and a low dielectric insulating film, or any of these.

In this case, as shown in FIG. 3, the pad electrode 5 and the active element 7 are placed on the same surface 1a of the semiconductor substrate 1.

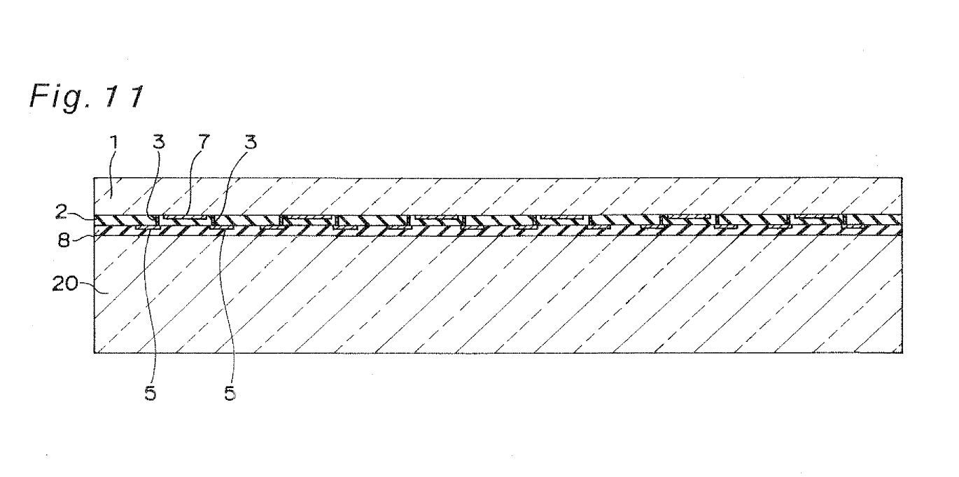

For example, the thickness of the interlayer insulating film 2 is 1 μm, and aluminum (800 nm in thickness) is used as the material for the pad electrode 5, with titanium nitride and titanium (200 nm in thickness, with titanium nitride and titanium combined with each other) being used as a close contact layer. In this case, as the close contact layer, only the titanium nitride layer may be used with a thickness of 150 nm, or only the titanium layer may be used with a thickness of 150 nm, or a combined layer of titanium nitride and titanium may be used with a combined film thickness of 150 nm. On the surface side of the pad electrode 5, for example, a silicon nitride layer (thickness: 1 μm) is formed as a passivation film 8. Moreover, for example, silicon doped into a p-type is used as the semiconductor substrate 1, and the thickness of this is reduced by using a grinder (FIG. 11). As shown in FIG. 10, for example, the thickness of the semiconductor substrate 1 is reduced to 200 μm. For example, the size of the pad electrode 5 is set to 150 μm in longitudinal length×150 μm in lateral length. Moreover, prior to the reducing process for the thickness by the grinder, for example, as shown in FIG. 10 and FIG. 11, the surface (surface on the passivation film 8 side) on the active element 7 side of the semiconductor substrate 1 is covered with a carrier substrate 20 so that the active element 7 and the other electrodes are protected by the carrier substrate 20. For example, glass is used as the carrier substrate 20.

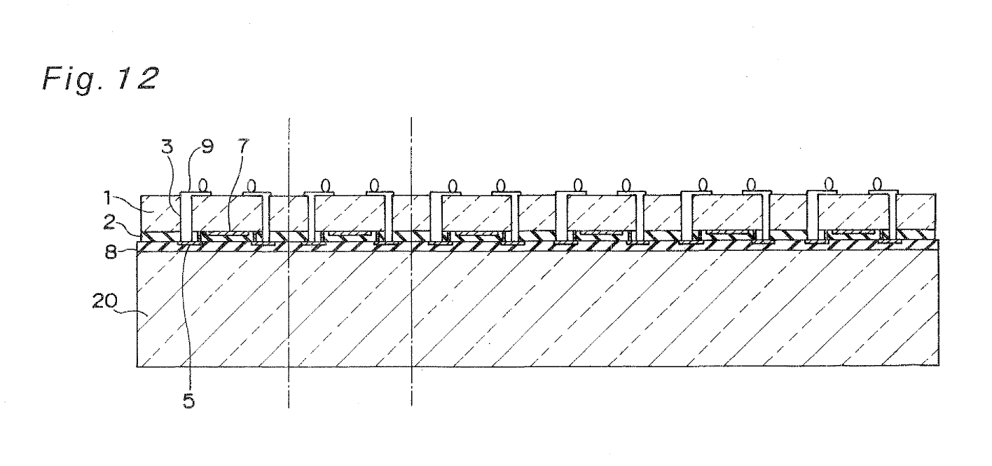

Next, as shown in FIG. 12, by dividing the semiconductor substrate 1 into individual pieces in the final process, a semiconductor device shown in FIG. 3 is manufactured.

Additionally, in FIG. 1, reference numeral 9 represents an electrode for BGA (Ball Grid Array) placed on the second surface 1b of the semiconductor substrate 1. This BGA-use electrode 9 and the pad electrode 5 are electrically connected with each other by the through electrode 3. In FIG. 3, reference numeral 9a represents each of ball bumps secured onto the BGA-use electrode 9.

In the semiconductor device having this structure, the following description will discuss first process S1 to sixth process S6 of a method for forming the through electrode 3 in the semiconductor substrate 1.

### (First Step 1)

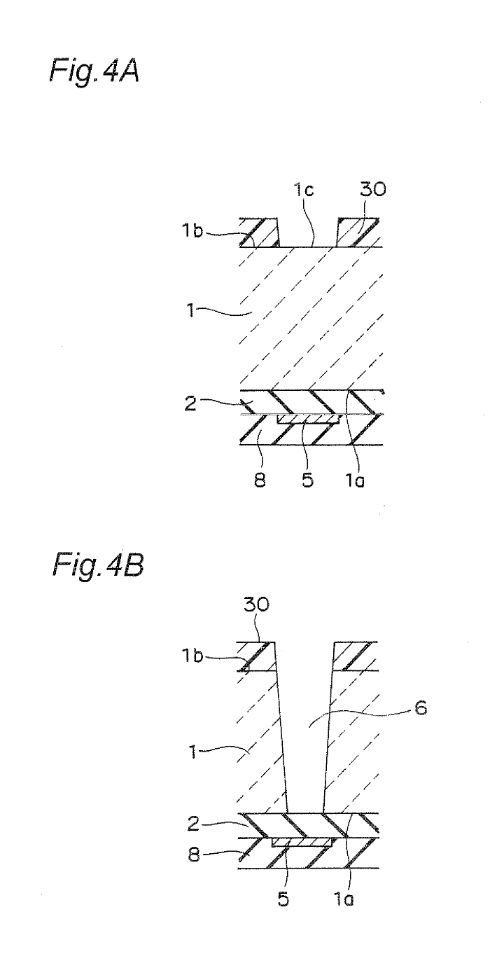

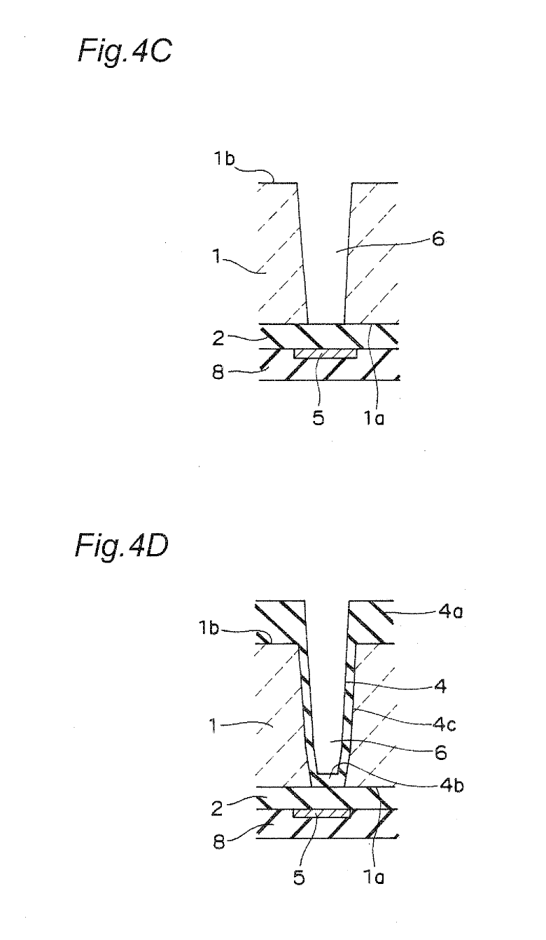

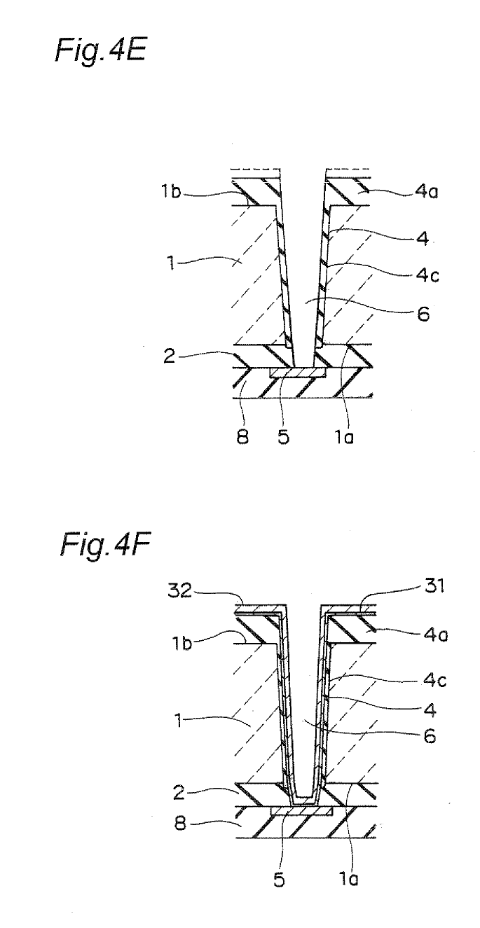

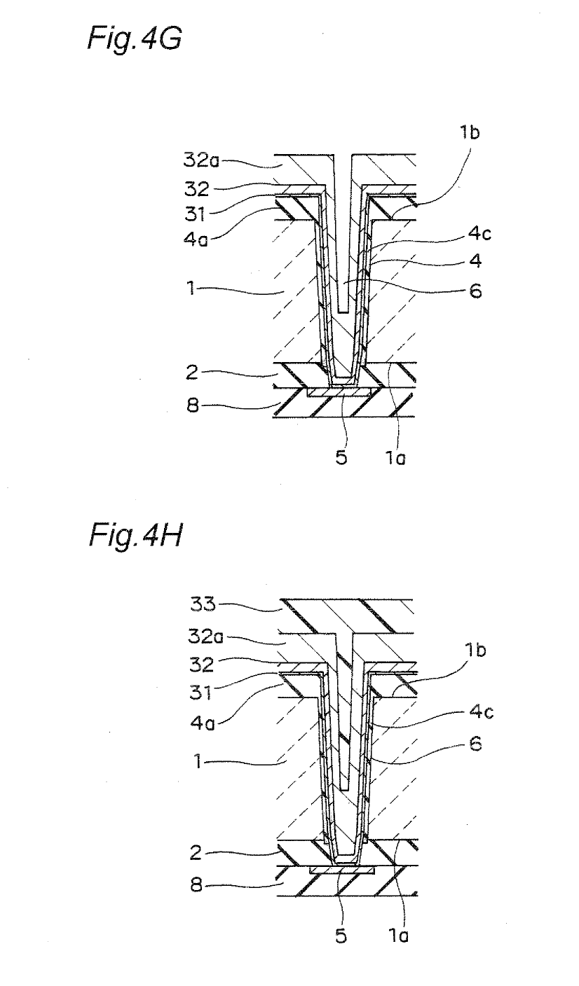

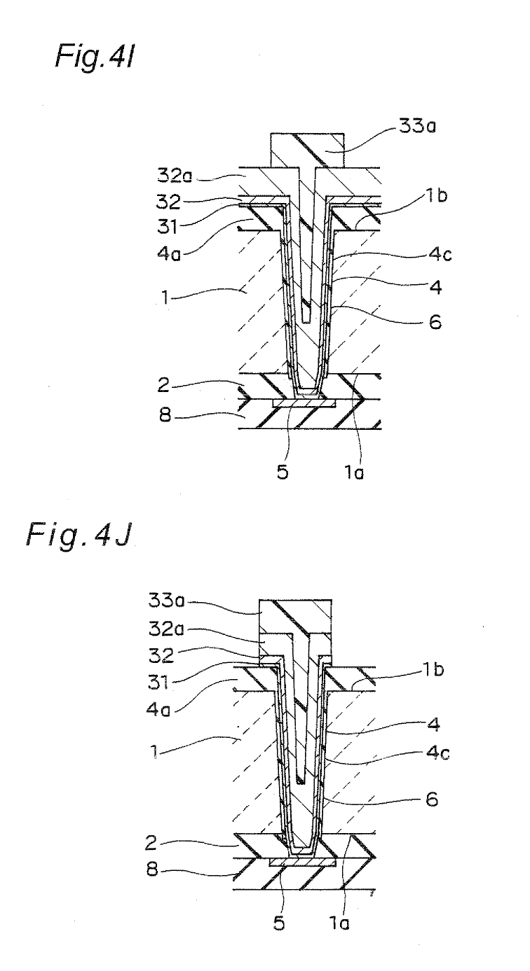

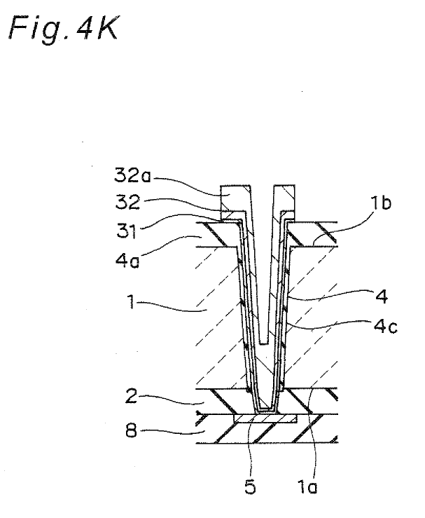

First, the first process S1 (see FIG. 2) is composed of three processes respectively shown in FIGS. 4A, 4B, and 4C.

In a resist mask forming process shown in FIG. 4A of the first process S1 (see FIG. 2), the metal electrode (pad electrode) 5 is formed on the surface (the first surface) 1a on which the active element 7 of the semiconductor substrate 1 is disposed. Moreover, the interlayer insulating film 2 is placed between the metal electrode 5 and the semiconductor substrate 1, and on the surface 1b on the side opposite to the semiconductor substrate 1, for example, a resist mask 30 having a thickness of 30 μm is formed on a portion other than a through electrode formation portion 1c.

Next, in a dry etching process used for forming a through hole shown in FIG. 4B of the first process S1 (see FIG. 2), the portion that is not covered with the resist mask 30 of the surface (the second surface) 1b on the side opposite to the surface 1a of the semiconductor substrate 1, that is, the through electrode formation portion 1c, is subjected to a dry etching process so that the semiconductor substrate 1 is etched to reach the interlayer insulating film 2; thus, a through hole 6 is formed through the semiconductor substrate 1. For example, the thickness of the semiconductor substrate 1 is 200 μm, and the diameter of the inlet of the through hole 6 is 100 μm, with the through hole 6 having a tapered shape with a tilt of 89° relative to the center axis of the through hole.

Next, in an asking process shown in FIG. 4C of the first process S1 (see FIG. 2), after the etching process, all the resist mask 30 is removed from the surface 1b on the side opposite to the semiconductor substrate 1 by asking.

After the dry etching process (first process S1), a washing process is desirably carried out. The washing process refers to a process used for removing etched product materials from the inner side of the through hole 6 as well as from the surface 1b on the side opposite to the semiconductor substrate 1, or for removing foreign matters therefrom. For example, as the washing liquid, pure water is preferably used upon removing the foreign matters, and sulfuric acid is preferably used for removing the reaction product materials after the oxide film dry etching process (see the first process S1 of FIG. 2).

### (Second Step S2)

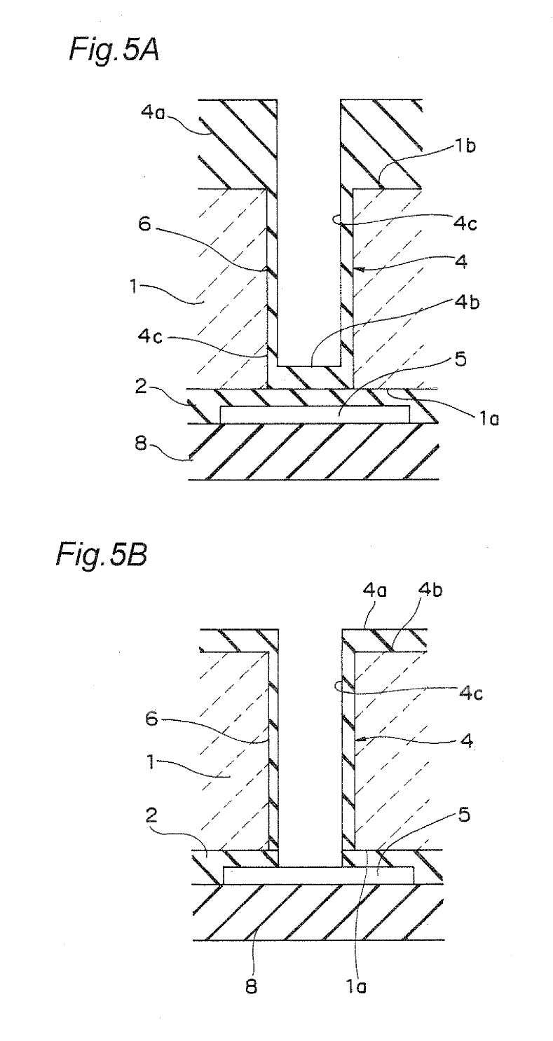

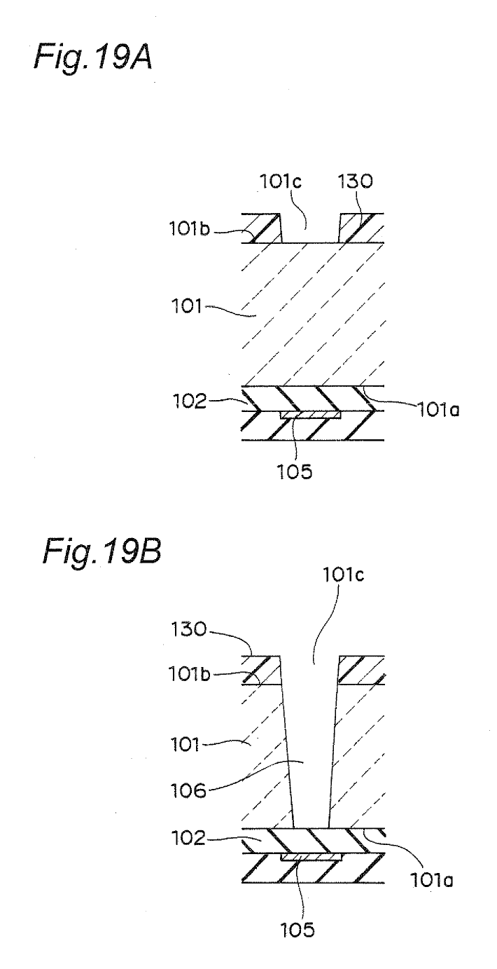

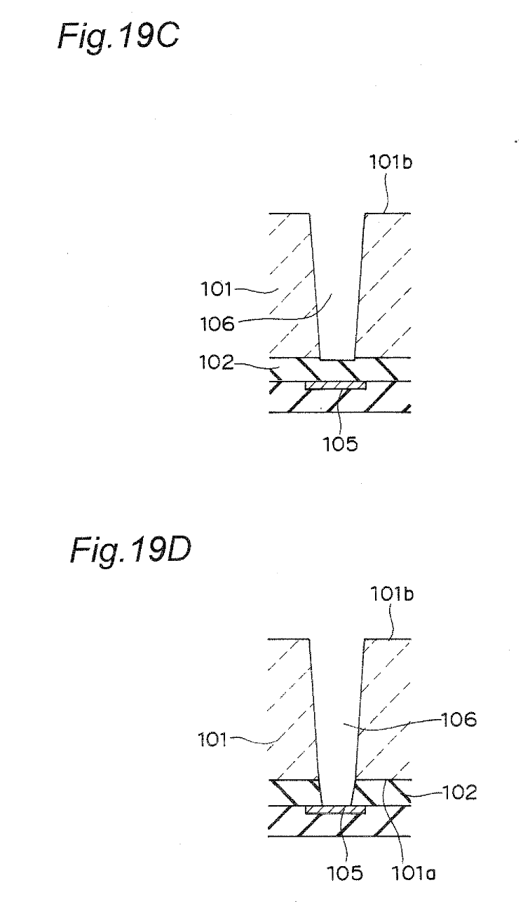

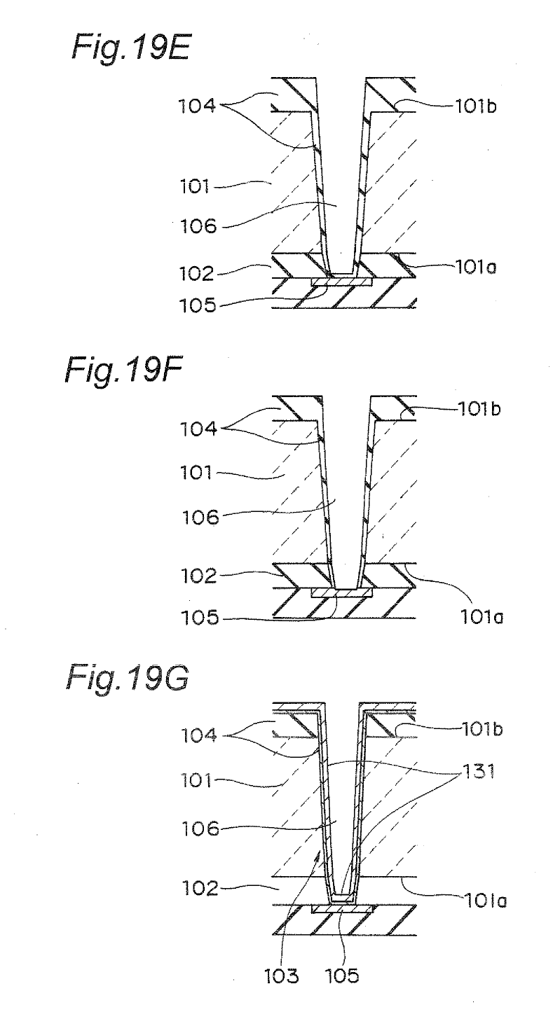

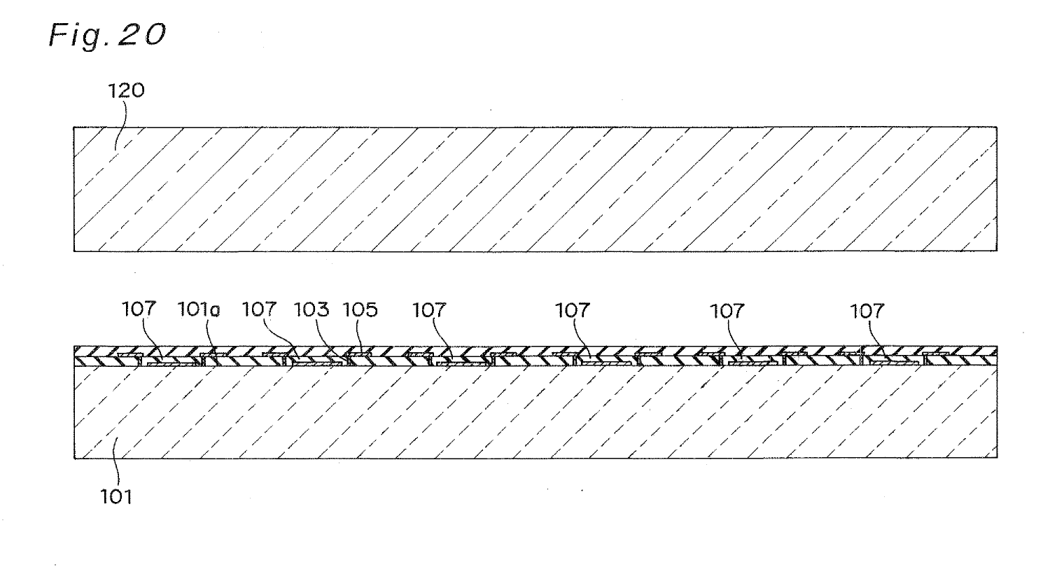

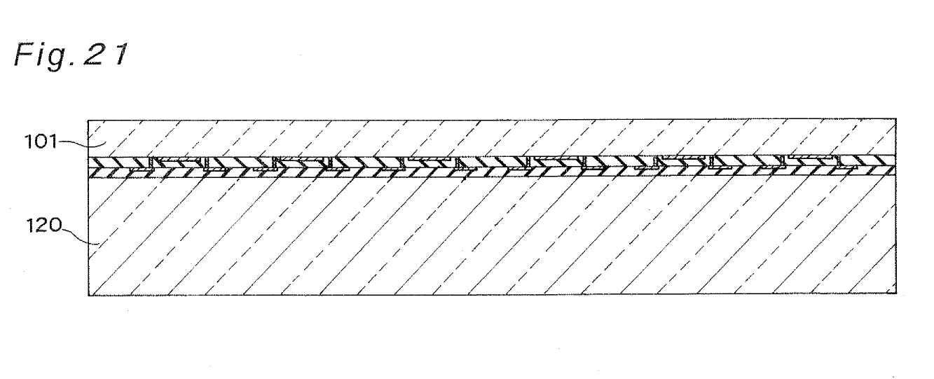

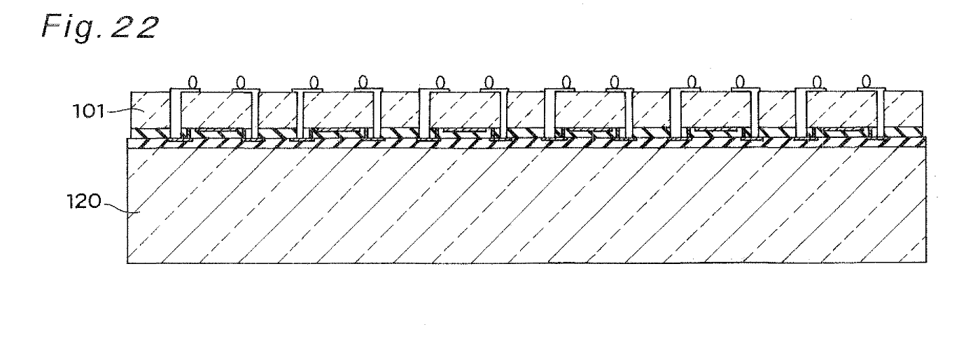

Thereafter, as shown in FIG. 4D, in the second process S2 (see FIG. 2), insulating films 4 are respectively formed by a CVD method on a bottom surface and a side surface inside the through hole 6 as well as on the surface (surface (the second surface) 1b on the side opposite to the semiconductor substrate 1) on the opening side of the through hole 6 of the semiconductor substrate 1. For example, the insulating film 4 (see 4a of FIG. 4D) of the surface 1b on the opening side of the through hole 6 has a thickness of 3 μm, and the insulating film 4 (see 4b of FIG. 4D) on the bottom surface of the through hole 6 has a thickness of 0.2 μm. Normally, in the CVD process, since the probability of radicals of TEOS (Tetraethoxysilane) reaching the inside of the through hole 6 becomes low, the deposition is carried out so as to make the thickness of the insulating film 4 (see 4a of FIG. 5A) on the surface 1b on the opening side of the through hole 6 of the semiconductor substrate 1 thicker than the thickness of the insulating film 4 (see 4b of FIG. 5A) on the bottom surface inside the through hole 6 as shown in FIG. 5A. For this reason, the thickness of the insulating film 4 (see 4c of FIG. 5A) adhered to the side surface of the through hole 6 near the surface 1b on the opening side inside the through hole 6 is substantially the same as the thickness of the insulating film 4 (see 4a of FIG. 5A) on the surface 1b on the opening side of the through hole 6 of the semiconductor substrate 1, and becomes gradually thinner toward the bottom surface of the through hole 6 from the surface 1b on the opening side of the through hole 6. Moreover, the thickness of the insulating film 4 (see 4c of FIG. 5A) adhered to the side surface near the bottom surface of the through hole 6 is substantially the same as the thickness of the insulating film 4 (see 4b of FIG. 5A) adhered to the bottom surface of the through hole 6. Additionally, FIG. 19D is a schematic view, and dimensions on the view are different from those of the explanation.

### (Third Process 3)

Next, as shown in FIG. 4E, in the third process S3 (see FIG. 2), all the portion (for example, a portion having a thickness of 0.2 μm) of the insulating film 4 (see 4b of FIG. 4D) on the bottom surface of the through hole 6 and one portion of the insulating film 4 (see 4a of FIG. 4D) of the surface 1b on the opening side of the through hole 6 of the semiconductor substrate 1 are removed by dry etching so that the insulating film 4 (see 4c of FIG. 4E) on the side surface of the through hole 6 is not etched; thus titanium on the lower surface side of the pad electrode 5 is exposed on the bottom surface of the through hole 6. That is, the insulating film 4 (see 4b of FIG. 4D) on the bottom surface of the through hole 6 and the interlayer insulating film 2, located from the bottom surface of the through hole 6 formed through the semiconductor substrate 1 to the pad electrode 5, are simultaneously etched. Thus, by removing the insulating film 4b and the interlayer insulating film 2 located from the bottom surface of the through hole 6 formed through the semiconductor substrate 1 to the pad electrode 5 by using etching, the through hole 6 is further extended to the inside of the interlayer insulating film 2 so that the electrode 5 on the first surface 1a of the semiconductor substrate 1 is exposed on the bottom surface of the through hole 6. Normally, in the case of using a parallel flat-plate type dry etching device, since the pressure inside a vacuum container of the dry etching device is high, the mean free path is short, with the result that since ions or radicals frequently collide with one another, it becomes difficult for the ions and radicals that contributes to the etching of the insulating film 4 and the interlayer insulating film 2 to reach the inside of the through hole 6. For this reason, the etching rate of the insulating film 4 on the bottom surface of the through hole 6 and the interlayer insulating film 2 becomes extremely lower than the etching rate of the insulating film 4 (see 4a of FIG. 4D) on the surface 1b on the opening side of the through hole 6, with the result that the insulating film 4 on the surface 1b disappears before the insulating film 4 on the bottom surface inside the through hole 6 and the interlayer insulating film 2 have been etched and removed.

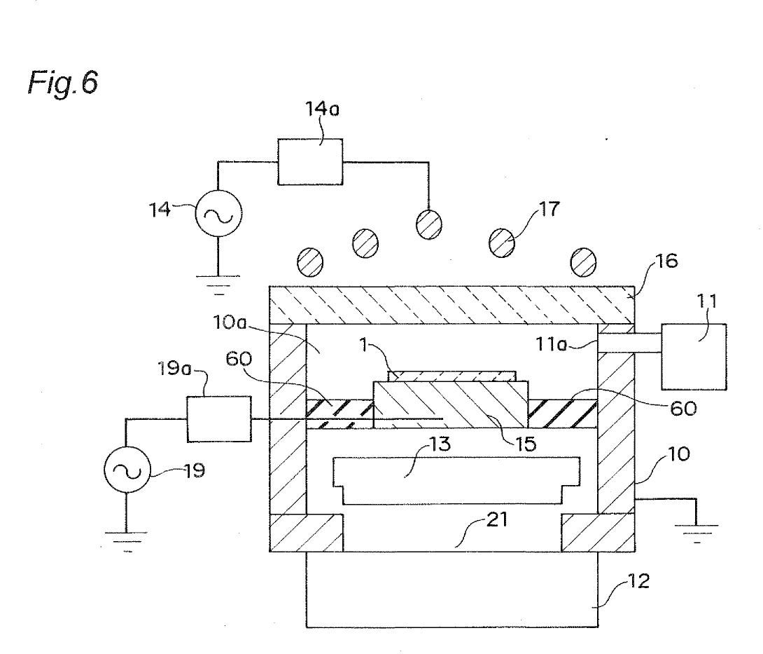

Therefore, by using an inductive coupling plasma device (see FIG. 6) that can maintain a discharge even under a reduced pressure, an etching process is carried out under a highly vacuumed state of 5 Pa or less so that it becomes possible to make the etching rate of the insulating film 4 on the bottom surface of the through hole 6 and the etching rate of the insulating film 4 on the surface 1b on the opening side of the through hole 6 can be made closer with each other. In practice, the lower limit value of the degree of vacuum is set to 0.1 Pa at which a discharge can be maintained.

The following description will discuss an etching process of the third process S3 by using, for example, the inductive coupling plasma device of FIG. 6.

As shown in FIG. 6, the semiconductor substrate 1 is placed on a lower electrode 15 inside a vacuum container 10 having, for example, a cylindrical shape, which has a vacuum chamber 10a therein and is grounded, and a mixed gas of CHF₃, oxygen, and argon having respective concentrations of 20 sccm, 2 sccm, and 100 sccm, serving as one example of an etching gas, is supplied into the vacuum container 10 from a gas introduction unit 11 serving as one example of a gas supply device through a gas supply inlet 11a on a side wall of the vacuum container 10. Moreover, a turbo molecule pump 12, serving as one example of an exhausting device that evacuates the inside of the vacuum container 10, a pressure adjusting valve for adjusting the degree of opening of an exhaust outlet 21 on a bottom surface of the vacuum container 10 and, a main valve 13 are used for maintaining the pressure inside the vacuum container 10 at 1 Pa. In this case, the turbo molecule pump 12, the pressure adjusting valve, the main valve 13, and the like form one example of a pressure control device. The lower electrode 15 is disposed through insulating members 60 that are a plurality of support pillars placed inside the vacuum container 10. In a manner so as to face the lower electrode 15, an inductive window 16, which is made of, for example, quartz and has a round shape, is formed on an upper round opening of the vacuum container 10. A coil 17 is placed near the upper surface on the outside of the inductive window 16. A high-frequency power supply 14 serving as one example of a plasma generating high-frequency power supply device is connected to the coil 17 via a matching device 14a. For example, high-frequency power of 13.56 MHz is supplied to the coil 17 by the high-frequency power supply 14 through the matching device 14a. Thus, an electromagnetic wave, generated by the coil 17, is allowed to transmit through the inside of the vacuum container 10 through the inductive window 16 so that a inductive coupling type plasma can be generated in a space above the lower electrode 15 and the periphery thereof inside the vacuum container 10. By applying high-frequency power of 1200 W to the inductive coupling plasma-use coil 17 from the high-frequency power supply 14 through the matching device 14a, with the above-mentioned pressure state being maintained, a plasma is generated in the vacuum container 10. Moreover, by applying high-frequency power of 200 W to the lower electrode 15 from the high-frequency power supply 19 through the matching device 19a, a self bias is generated. Thus, ions in the plasma are accelerated toward the semiconductor substrate 1 so that the insulating film 4 on the second surface 1b of the semiconductor substrate 1, the insulating film 4 inside the through hole 6, and the interlayer insulating film 2 are subjected to an etching process. A gas to be introduced into the vacuum container 10 upon dry etching, is a gas containing at least one kind of perfluorocarbon. In the above-mentioned example, CHF₃ is used; however, not limited by this, perfluorocarbon of CF₄, C₄F₈, C₂F₆, or CH₂F₂ may be used. The third process S3 can be carried out by using such a device.

In this case, in the above-mentioned second process S2 (see FIG. 4D), among a thickness A of the insulating film 4 (see 4a of FIG. 4D) deposited on the second surface 1b of the semiconductor substrate 1, a thickness B of the insulating film 4 (see 4b of FIG. 4D) deposited on the bottom surface of the through hole 6, a thickness C of the interlayer insulating film 2 on the first surface 1a of the semiconductor substrate 1, an etching rate D at which the insulating film 4 (see 4a of FIG. 4D) is removed from the second surface 1b of the semiconductor substrate 1 in the third process S3 (see FIG. 4E), and an average etching rate E at which the insulating film 4 (see 4b of FIG. 4D) on the bottom surface of the through hole 6 formed in the second process S2 and a thickness C of the interlayer insulating film 2 are etched by using the third process S3, the following expression is satisfied.

(B+C)/A<E/D (Expression 1)

In other words, the thickness C of the interlayer insulating film 2 beneath the pad electrode 5, the thickness A of the insulating film 4 (see 4a of FIG. 4D) on the second surface 1b of the CVD semiconductor substrate 1 of the second process S2 and the thickness B of the insulating film 4 (see 4b of FIG. 4D) on the bottom surface of the through hole 6, the etching rate D of the insulating film 4 (see 4a of FIG. 4D) of the second surface 1b of the semiconductor substrate 1 in the dry etching process of the third process S3, and the etching rate E of the insulating film 4 (see 4b of FIG. 4D) on the bottom surface of the through hole 6 and the thickness C of the interlayer insulating film 2 are set so as to satisfy the above-mentioned relational expression. By carrying out a process under the thickness and dry etching conditions that satisfy the above-mentioned expression 1, it is possible to obtain the through hole 6 and the insulating film 4 having cross-sectional structures shown in FIG. 5B.

By taking into consideration the in-plane uniformity on the entire surface of the semiconductor substrate 1, the value of (E/D) may be set to a value in a range of (E/D)×(1.05 to 1.10), with a safety coefficient of 5% to 10% being preliminarily estimated.

In this case, as an example of the calculation method for the etching rate E, any of the following methods may be used.

(1) Among a plurality of through holes 6 formed through the semiconductor substrate 1, an average etching rate of the insulating film(s) 4b on the bottom surface(s) of at least one or more through holes 6 is defined as the etching rate E.

(2) An etching rate is calculated on at least one of films forming the insulating film 4b on each of the bottom surfaces of a plurality of through holes 6, and this is defined as the entire etching rate E.

(3) An etching rate is calculated on at least one of films forming the insulating film 4c on each of the bottom surfaces of a plurality of through holes 6, and by multiplying the etching rate thus calculated by a coefficient corresponding to each of the insulating films 4c, values are obtained, and are then averaged so that an averaged etching rate is defined as the etching rate E.

(4) The etching rates of the insulating films 4a on the second surface 1b of the semiconductor substrate 1 are calculated, and the etching rates thus calculated are multiplied by coefficients used for converting them to the etching rates of the insulating films 4b on the bottom surfaces of the through holes 6 so that values are obtained, and are then averaged; thus, an averaged etching rate is defined as the etching rate E.

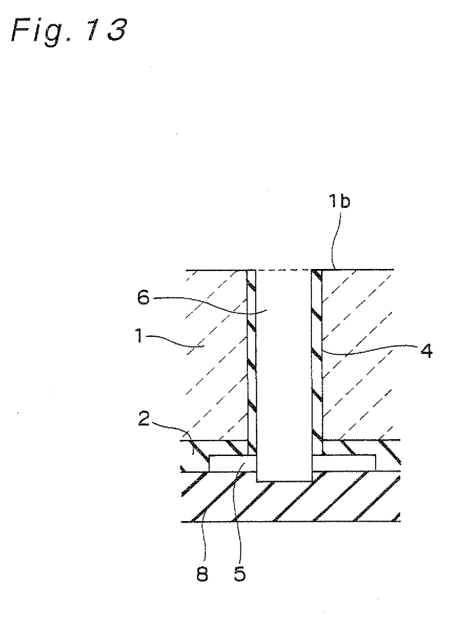

In this case, in the second and third processes S2 and S3, in the case where the dry etching method is carried out by using a conventional method, as shown in FIG. 13, the insulating film 4 on the second surface 1b of the semiconductor substrate 1 disappears to cause a short circuit.

The following description will discuss one working example of the third process S3 of the present embodiment. For example, suppose that the thickness C of the interlayer insulating film 2 beneath the pad electrode 5 is 1 μm, that the thickness A of a deposit film corresponding to the insulating film 4 on the second surface 1b of the semiconductor substrate 1 and the thickness B of the insulating film 4 on the bottom surface of the through hole 6 are respectively set to 3 μm and 0.2 μm in the second process S2, and that the etching rate D of the insulating film 4 on the second surface 1b of the semiconductor substrate 1 in the third process S3 and the etching rate E of the insulating film 4 on the bottom surface of the through hole 6 and the thickness C of the interlayer insulating film 2 are respectively set to 400 nm/min and 300 nm/min. Thus, the expression 1 is substituted by the respective values.

(B+C)/A=(0.2 μm+1 μm)/3 μm=3 μm=0.4

E/D=300 nm/min/400 nm/min=0.75

0.4<0.75

In this manner, the expression 1 is satisfied in this working example.

In this case, as a period of time required for etching the thickness B=0.2 μm of the insulating film 4 on the bottom surface of the through hole 6 and the thickness C=1 μm of the interlayer insulating film 2 at an etching rate E=300 nm/min of the insulating film 4 on the bottom surface of the through hole 6, 4 minutes are obtained from (B+C)/E=(0.2 μm+1 μm)/300 nm/min. Therefore, the etching process time in the third process S3 corresponds to a process for 4 minutes in the above-mentioned calculations; however, by taking into consideration ±5% as the in-plane uniformity on the entire surface of the semiconductor substrate 1, an etching process for 5 minutes was carried out, with an over-etching of about 30% being taken into consideration. At this time, all the insulating film 4 (see 4b of FIG. 4D) on the bottom surface of the through hole 6 is removed so that titanium on the lower surface side of the pad electrode 5 is exposed on the bottom surface of the through hole 6. Moreover, a thickness F of the remaining insulating film 4a of the insulating film 4 (see 4a of FIG. 4D) on the second surface 1b of the semiconductor substrate 1 was 1 μm. Supposing that the thickness F of the insulating film 4 on the second surface 1b of the semiconductor substrate 1 is permissible up to 300 nm (in other words, the remaining film thickness is permissible up to 300 nm), the thickness of the insulating film 4A to be deposited on the second surface 1b of the semiconductor substrate 1 may be set to 2.3 μm in the second process S2.

### (Fourth Process S4)

In the fourth process S4 that continues to the third process S3 (see FIG. 2), first, a seed layer 32 for use in plating in a fifth process S5 is formed (see FIG. 4F) so as to allow a metal film to adhere to the inside of the through hole 6 by a sputtering method. For example, a copper seed layer 32 is formed so as to use copper as an electrode material for the through electrode 3. Moreover, titanium may be used as one example of a close contact layer 31 of the seed layer 32. For example, the thickness of the titanium close contact layer 31 that adheres to the bottom surface of the through hole 6 is set to about 50 nm. Thus, the close contact layer 31 made of titanium is first formed on the side surface and the bottom surface of the through hole 6 as well as on the second surface 1b of the semiconductor substrate 1 on the opening side of the through hole 6 by using a sputtering method. Thereafter, the seed layer 32 is formed on the close contact layer 31 by a sputtering method.

### (Fifth Process S5)

Next, in the fifth process S5 (see FIG. 2), by allowing an electric current to flow through each of the titanium close contact layer 31 and the copper seed layer 32, an electrolytic plating process of copper is carried out, and copper is subsequently grown on the inner side of the through hole 6 and the second surface 1b so that a copper conductive layer 32a is formed (see 32a of FIG. 4G). As a result, the metal layers 31, 32, and 32a are formed on the second surface 1b of the semiconductor substrate 1, and the metal layers 31, 32, and 32a are also formed on the side surface and the bottom surface of the through hole 6 so that a through electrode 3 is formed, and by using the through electrode 3, the electrode 5 on the second surface 1a of the semiconductor substrate 1 exposed in the third process S3 and the metal layers 31, 32, and 32a of the second surface 1b of the semiconductor substrate 1 are connected with each other by the through electrode 3.

### (Sixth Process S6)

Next, a resist mask 33, which is used for forming a circuit on the copper conductive layer 32a formed on the second surface 1b on the opposite side of the semiconductor substrate 1, is formed in a sixth process S6 (see FIG. 2). That is, after having coated the entire surface of the copper conductive layer 32a with the resist mask 33 (see FIG. 4H), unnecessary portions for the circuit formation are exposed so that the exposed portions are removed by developing, and by baking the remaining resist mask 33a, the resist mask 33a is formed only on the circuit formation portion (see FIG. 4I). Thereafter, the conductive layer 32a on the portions that are not covered with the resist mask 33a is removed by etching (see FIG. 4J).

Lastly, the remaining resist mask 33a is removed by asking so that an electrode wiring constructed by the conductive layer 32a is formed (see FIG. 4K).

The following description will discuss one working example. In the CVD process of the second process S2, a parallel flat-plate type CVD device was used. A TEOSCVD process using TEOS as a gas is carried out. A TEOS gas having a flow rate of 2 g/min was supplied into a CVD chamber, and a plasma is generated in the CVD chamber so that an insulating film 4 was deposited on the semiconductor substrate 1. With respect to the formation of the insulating film 4 by the CVD method, it is determined whether or not deposition is easily made inside the through hole 6 by a pressure, in the same manner as in the dry etching described earlier. In addition to radicals reaching the semiconductor substrate 1, the amount of adhesion onto the bottom surface of the through hole 6 is determined by the amount of radicals that invade into the through hole 6 so that the thickness of the insulating film thus deposited and formed is subsequently determined. The insulating film 4 deposited and formed is a silicon oxide film or a silicon nitride film, which is formed by a plasma CVD process, a thermal CVD process, or a normal pressure CVD process. In this case, the CVD process is exemplified as the deposition method; however, a silicon oxide film may be produced by sputtering, and a synthesized resin or a silicon oxide film may be produced by using a vapor deposition method. By using these production methods, in particular, it becomes possible to reduce the amount of radicals that reach the inside of the through hole 6 and consequently to carry out a depositing process so that the thickness of the insulating film 4 (see 4a of FIG. 5A) of the surface 1b on the opening side of the through hole 6 of the semiconductor substrate 1 is made thicker than the thickness of the insulating film 4 (see 4b of FIG. 5A) on the bottom surface inside the through hole 6.

In the case where the pressure inside the vacuum container 10 is high in the third process S3, the mean free path becomes shorter to increase the probability of ions colliding with neutral particles, with the result that the ions are decelerated and considered not to reach the bottom surface of the through hole 6.

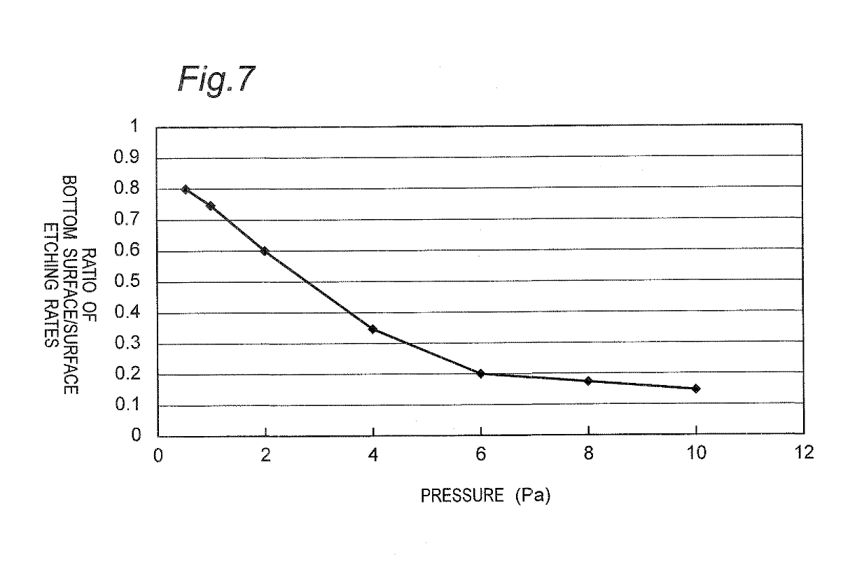

FIG. 7 shows a pressure dependence of a ratio (E/D) between an etching rate D of an insulating film 4 of the second surface (surface) 1b of a semiconductor substrate 1 and an etching rate E of an insulating film 4 on the bottom surface inside a through hole 6. As the pressure inside the vacuum container 10 becomes a highly vacuumed state, the etching rate E of the insulating film 4 on the bottom surface inside the through hole 6 is improved to indicate that the etching rate D of the insulating film 4 on the bottom surface inside the through hole 6 comes closer to the etching rate E of the insulating film 4 on the second surface 1b of the semiconductor substrate 1.

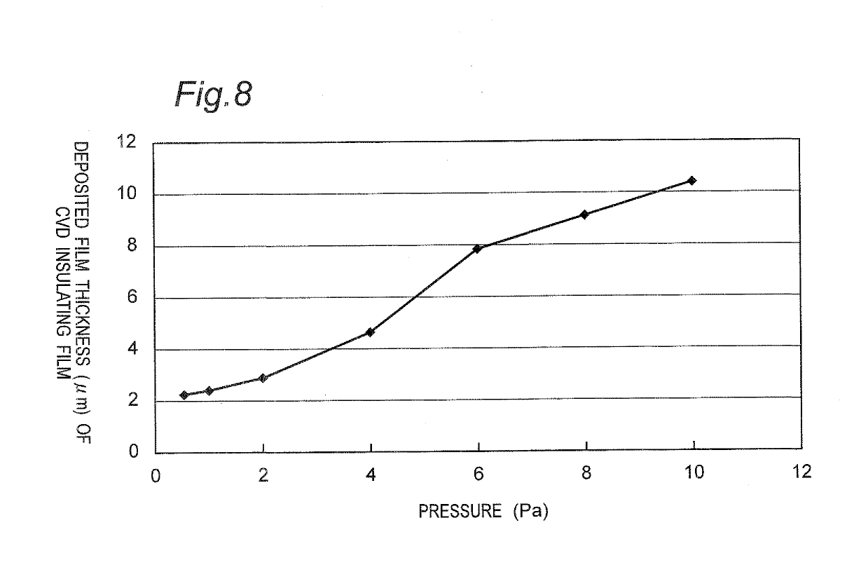

FIG. 8 shows a pressure dependence of a thickness of an insulating film 4 required for allowing the thickness F of the remaining insulating film 4 on the second surface 1b of the semiconductor substrate 1 to be set to 0.3 μm in the third process S3 described in relation to the expression 1. Since the etching rate E of the insulating film 4 on the bottom surface inside the through hole 6 is reduced, the etching process time is prolonged as the pressure inside the vacuum container 10 increases.

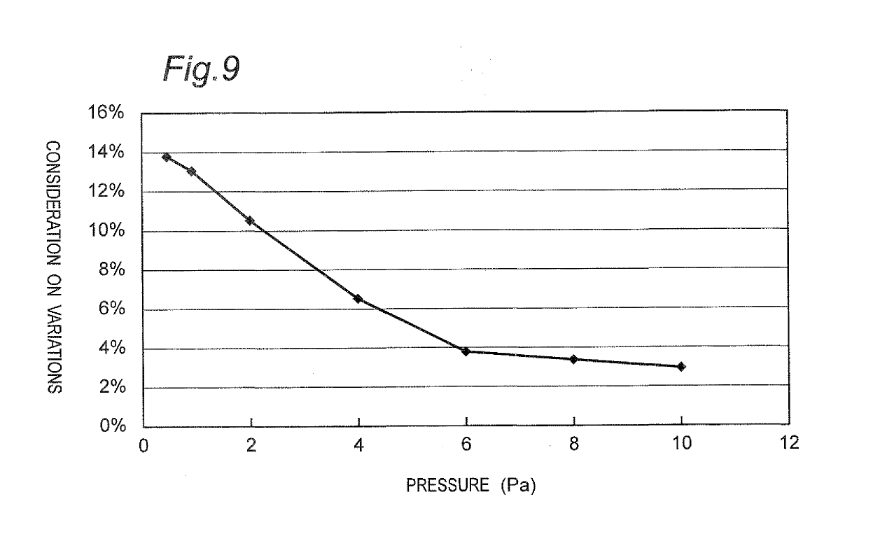

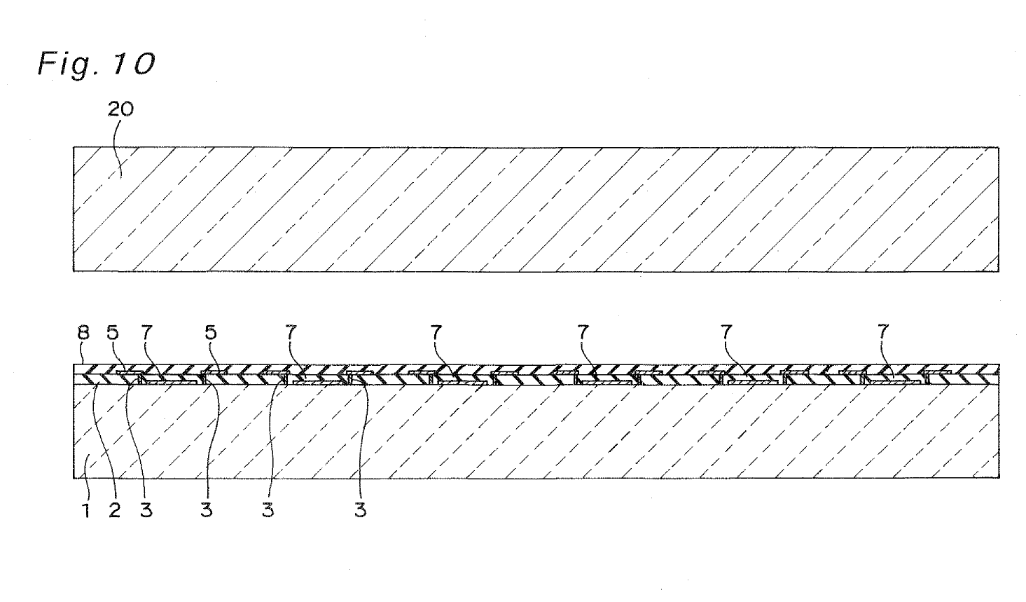

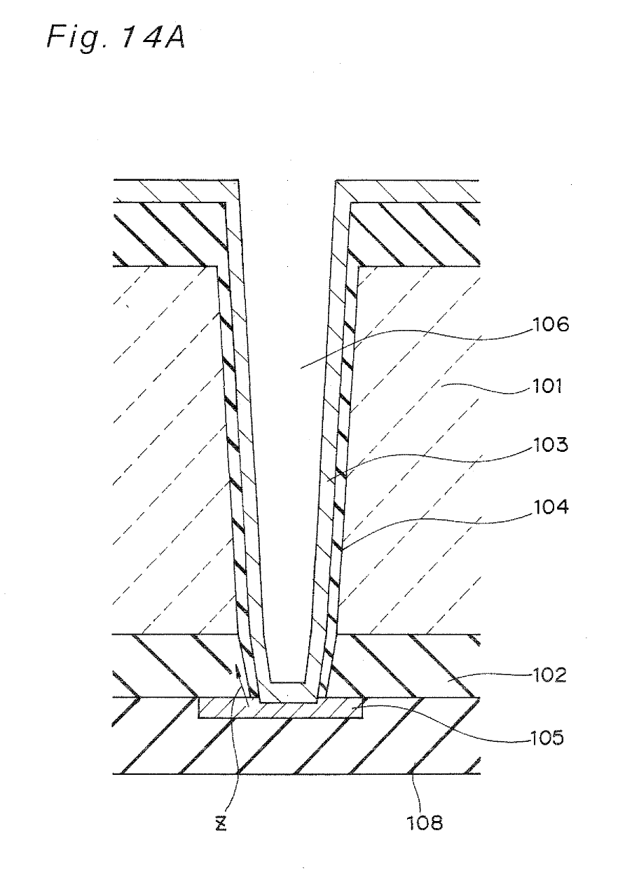

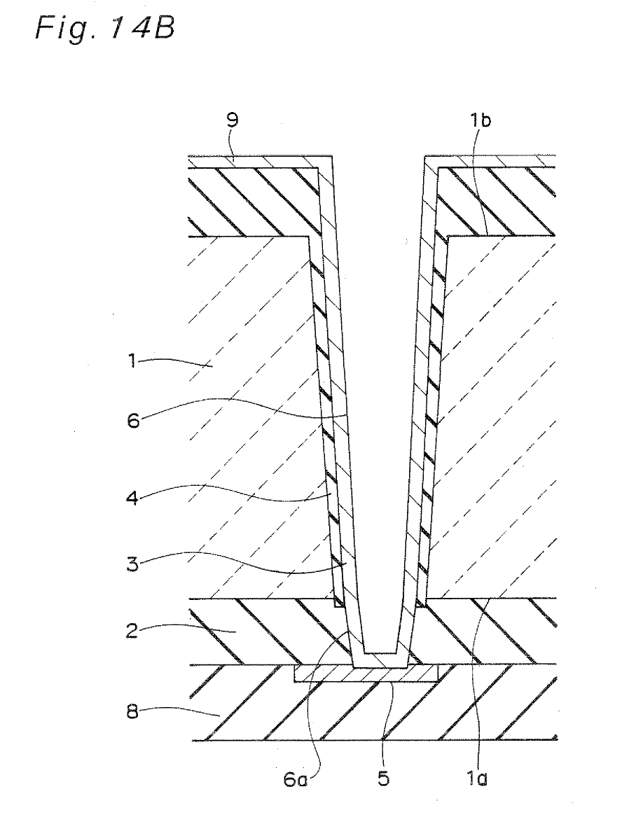

FIG. 9 shows in-plane uniformity of an etching rate that is required when the thickness F of the remaining insulating film 4 on the second surface 1b of the semiconductor substrate 1 after the etching process is set to 0.3 μm. For example, in the case where the pressure inside the vacuum container 10 is 1 Pa, the required in-plane uniformity of the etching rate is ±13%, while the actual in-plane uniformity of the etching rate is about ±5%; thus, the thickness 0.3 μm can be sufficiently ensured. However, in the case where the pressure inside the vacuum container 10 is 8 Pa, the required in-plane uniformity of the etching rate is ±3.3%, and this means that when the actual in-plane uniformity of the etching rate is about ±5%, one portion of the in-plane insulating film 4 is removed to make the silicon semiconductor substrate 1 exposed. For this reason, the silicon semiconductor substrate and the electrode are made in contact with each other to cause a leak current (see an arrow Z of FIG. 14A). In order to prevent the occurrence of such a leak current, the insulating film 4 on the second surface 1b of the semiconductor substrate 1 is maintained so as to have a required thickness of 0.3 μm or more, and since the required in-plane uniformity of the etching rate is about ±5% in the dry etching of the third process S3, the pressure inside of the vacuum container 10 during the dry etching process of the third process S3 is preferably set to 5 Pa or less. In this case, the reason that the remaining thickness F of the insulating film 4 on the second surface 1b of the semiconductor substrate 1 is set to 0.3 μm or more is because it is possible to ensure a sufficient insulation pressure resistant property. With this arrangement, as will be described later in detail, the silicon semiconductor substrate 1 and the electrode 5 are not connected with each other, as shown in FIG. 14B, so that it is possible to prevent a leak current from occurring between the two members.

Moreover, in order to maintain a discharge under a pressure of 5 Pa, a high-density plasma source is required, and the present embodiment has exemplified an inductive coupling plasma source as the high-density plasma source; however, not limited to this, an electronic cyclotron resonance plasma, helicon plasma, VHF plasma, or magnetron RIE source may be preferably applied.

In the fourth process S4 of the present embodiment, the explanation has been given by exemplifying generation of titanium for the close contact layer and copper for the electrode seed layer by using sputtering; however, polysilicon or tungsten may be generated as the close contact layer and the electrode seed layer by using CVD.

In this case, the explanation has been given by exemplifying a structure in which a circuit disposed on the semiconductor substrate 1 is an active element 7, and the active element 7 may be prepared as a resistance-variable or voltage-variable or temperature-variable element in which a transistor, a charge coupling element, a PN junction, or a piezo element is used, or an SHG (secondary high-harmonic generation element), or an optical waveguide amplifying element such as an element utilizing a non-linear optical effect, or a liquid crystal, or a light-emitting element.

In accordance with the embodiment, in the third process S3, the insulating film 4b on the bottom surface of the through hole 6 formed in the second process S2 and the interlayer insulating film 2 located on the first surface 1a of the semiconductor substrate 1 are simultaneously subjected to an etching process, and the insulating film 4b on the bottom surface of the through hole 6 and the interlayer insulating film 2 are subsequently removed so that the electrode 5 on the first surface 1a of the semiconductor substrate 1 is exposed. Therefore, in comparison with a conventional structure in which the process for removing the interlayer insulating film by using an etching method and the process for removing the insulating film on the bottom surface of the through hole are carried out separately, since the etching process can be commonly carried out by a single process, the number of processes can be reduced, with the number of required devices being reduced; thus, the processes can be carried out in a short period of time, making it possible to increase the productivity and also to reduce the manufacturing costs. In this case, in order to commonly utilize the conventional dry etching process for removing the interlayer insulating film inside the through hole and dry etching process for removing the insulating film on the bottom surface of the through hole, for example, the thickness of the insulating film 4 on the second surface 1b of the semiconductor substrate 1, the etching rate, and the like of the CVD and dry etching processes may be set based upon the aforementioned expression 1. By using this method, devices corresponding to one process become unnecessary so that it becomes possible to ensure effects such as short-time processes and realize reduction of the manufacturing costs.

Moreover, the number of times in which the pad electrode 5 on the surface on the active element side is exposed is reduced to one time, making it possible to reduce the possibility of the pad electrode 5 being scraped; thus, it becomes possible to positively electrically connect the pad electrode 5 with the conductive layer 32a on the surface 1b (the second surface) on the side opposite to the surface 1a on the active element side, and also to simultaneously prevent a short-circuit between the through electrode 3 and the semiconductor substrate 1, thereby making it possible to improve the reliability.

The following description will further discuss a relationship between operations of the semiconductor device formed by the semiconductor substrate 1 having the through electrode 3 prepared by the method of forming the through electrode 3 of the embodiment and the structure near the through electrode 3.

FIG. 1 is a cross-sectional view showing the semiconductor substrate 1 having the through electrode 3 prepared by the method of forming the through electrode 3 of the embodiment of the present invention, and FIG. 3 is a cross-sectional view showing the semiconductor device having the semiconductor substrate 1. FIG. 14B is a cross-sectional view showing the neighboring portion of the pad electrode 5 of the through electrode 3.

During an operation of the semiconductor device, the semiconductor substrate 1 has a temperature rise. At this time, the temperature of the semiconductor substrate 1 rises to about 80° C. to 120° C. In the case where the operation ensuring temperature upon operation of the semiconductor device is set to minus 55° C. or more, since the maximum temperature rise is 120° C.+55° C.=175° C., the temperature can be estimated as about 170° C. Since the linear expansion coefficient of silicon of the semiconductor substrate 1 is 2.6 E⁻⁶/K to 3.5 E⁻⁶/K, the semiconductor substrate 1 having a thickness of 200 μm is expanded in the thickness direction by about 0.1 μm. On the other hand, since the linear expansion coefficient of a silicon oxide film serving as the insulating film 4 is 0.4 E⁻⁶/K to 0.55 E⁻⁶/K, the expansion of the insulating film 4 in the thickness direction is 0.01 μm, with an amount of strain of the insulating film 4 being set to 0.05%. Since Young's modulus of the silicon oxide film serving as the insulating film 4 is 73 GPa, the inner stress of the insulating film 4 becomes 37 MPa.

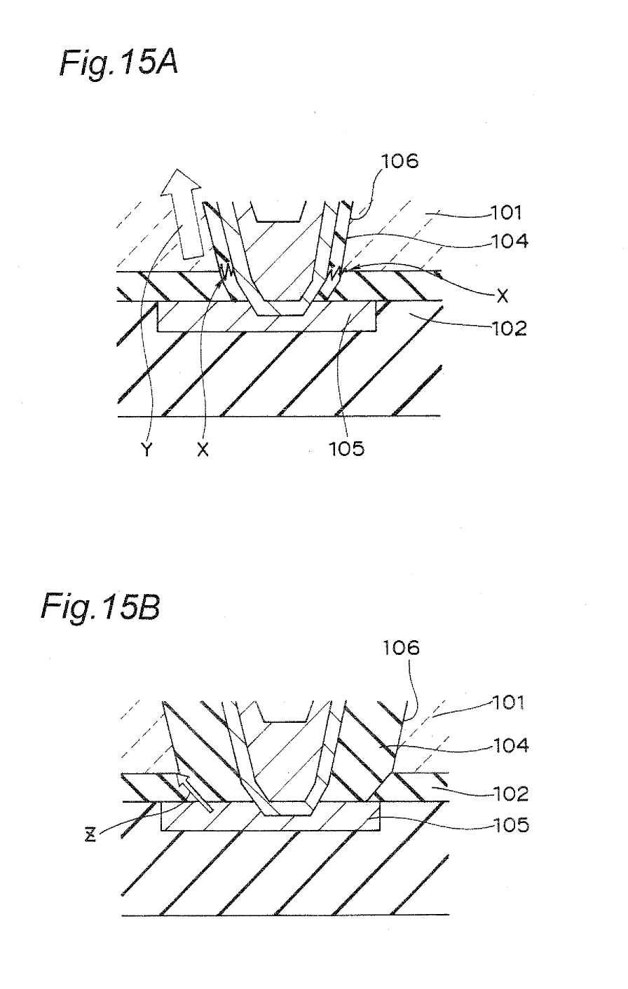

In the case where a film that is film-formed inside the through hole 6 by using a CVD process as the insulating film 4 is a silicon oxide film, the insulating film 4 does not have a rupture due to only the inner stress. However, when operated as the semiconductor device, the silicon oxide film serving as the insulating film 4 is continuously subjected to a thermal stress repeatedly, with the result that the service life of the insulating film 4 is shortened to sometimes cause a rupture in the insulating film 4 at a portion having the greatest stress. For example, in the conventional structure shown in FIGS. 14A and 15A, the shape of the insulating film 104 inside the through hole 106 of the silicon semiconductor substrate 101 (the tilt angle of the interface between the semiconductor substrate 101 and the insulating film 104 relative to the thickness direction of the semiconductor substrate 101) becomes a tapered shape having an angle about 89°, and the shape of the interlayer insulating film 102 (the tilt angle of the interface between the insulating film 104 and the interlayer insulating film 102 relative to the thickness direction of the semiconductor substrate 101) becomes a tapered shape having an angle about 60°. For this reason, in the insulating film 104 of the silicon oxide film formed by the CVD process, since the tilt angle changes from about 89° to about 60° near the interface (see an arrow X in FIG. 15A) between the interlayer insulating film 102 and the semiconductor substrate 101, a tensile vector relating to the insulating film 104 is changed. As a result, the highest stress is applied to the insulating film 104 (see an arrow Y in FIG. 15A), and when the usage as the semiconductor device is repeatedly carried out, the silicon oxide film serving as the insulating film 104 tends to have a rupture. For this reason, midway during the use of the semiconductor device, the insulating property thereof deteriorates to cause an erroneous operation of the semiconductor device and an occurrence of a fire in some cases.

Moreover, since the interface resistance is low in the insulating film 104 and the silicon of the semiconductor substrate 101 near the interlayer insulating film 102, an electric current tends to easily flow from the electrode 105 to the semiconductor substrate 101 along the interface between the interlayer insulating film 102 and the insulating film 104 to cause a probability of dielectric breakdown or an occurrence of an electric leak (see an arrow Z in FIG. 14A and an arrow Z in FIG. 15B).

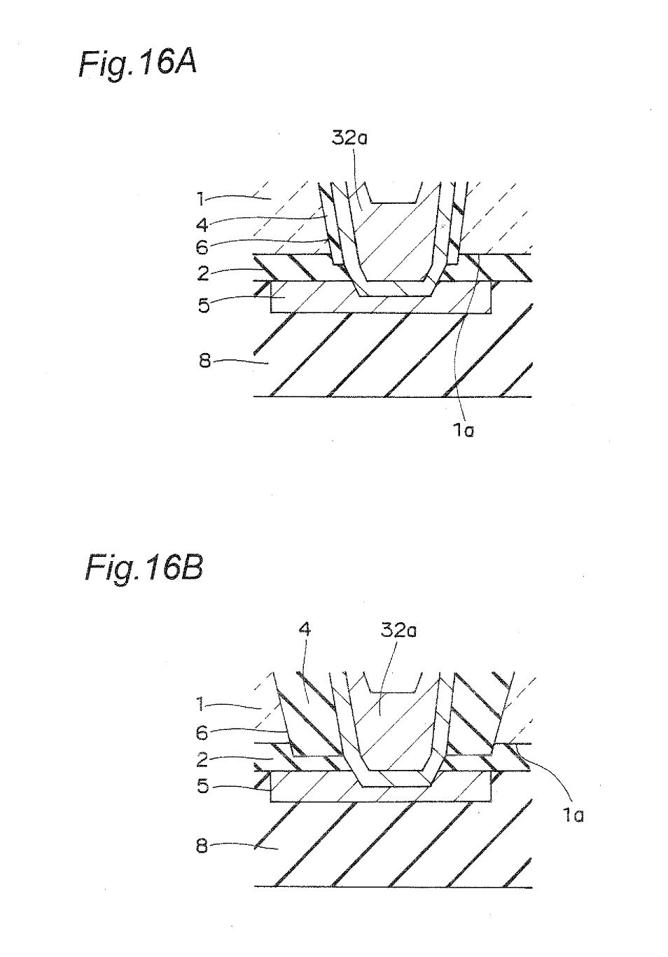

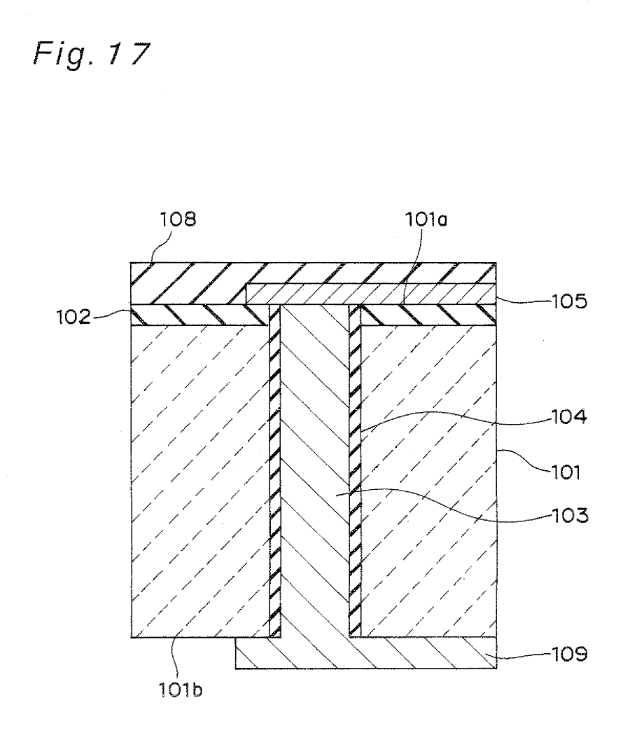

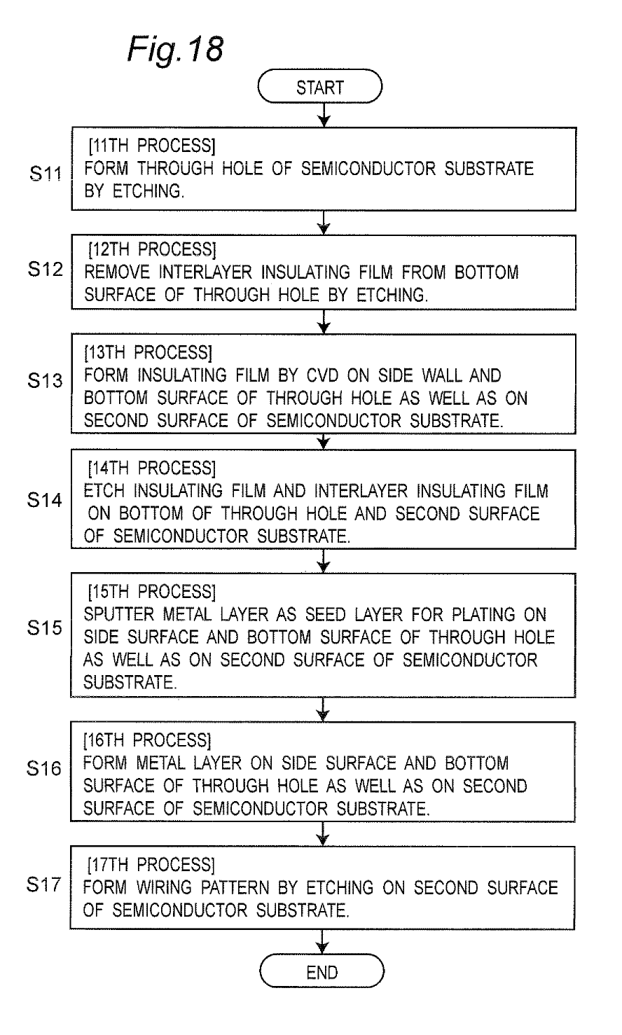

In contrast, in the embodiment of the present invention, since the insulating film 4 on the bottom surface of the through hole 6 formed by the CVD process and the interlayer insulating film 2, in the second process S2 and the third process S3, are simultaneously processed so that an insulating structure can be formed on the semiconductor substrate 1 by using two kinds of insulating films, that is, the insulating film 4 and the interlayer insulating film 2, relative to the metal electrode (conductive layer) 32a to be film-formed in the fourth process S4 (see FIGS. 16A and 16B). That is, as shown in FIGS. 16A and 16B in an enlarged manner, within the thickness dimension of the semiconductor substrate 1, the metal electrode 32a is insulated from the semiconductor substrate 1 by the insulating film 4 formed on the side surface of the through hole 6. Between the first surface 1a of the semiconductor substrate 1 and the electrode 5, since one portion of the insulating film 4 intrudes into the interlayer insulating film 2, the metal electrode 32a is insulated from the semiconductor substrate 1 by the insulating film 4 intruded into the interlayer insulating film 2, and designed to be then insulated only by the interlayer insulating film 2.

In this structure, for example, the shape of the insulating film 4 inside the through hole 6 of the silicon semiconductor substrate 1 (the tilt angle of the interface between the semiconductor substrate 1 and the insulating film 4 relative to the thickness direction of the semiconductor substrate 1) becomes a tapered shape having an angle about 89°, and the shape of the interlayer insulating film 2 (the tilt angle of the interface between the metal electrode (conductive layer) 32a and the interlayer insulating film 2 relative to the thickness direction of the semiconductor substrate 1) becomes a tapered shape having an angle about 60°. For this reason, in the insulating film 4 of the silicon oxide film formed by the CVD process, the insulating film 4 inside the through hole 6 is intruded into the interlayer insulating film 2 near the interface between the interlayer insulating film 2 and the semiconductor substrate 1, with the result that no tilt angle is formed near the interface; thus, no tensile vector is exerted onto the insulating film 4 near interface between the interlayer insulating film 2 and the semiconductor substrate 1. Consequently, it becomes possible to improve the reliability of the device, that is, the semiconductor device.

Moreover, in the silicon etching in the first process S1, the selection ratio of the interlayer insulating film 2 is about 200 relative to the silicon of the semiconductor substrate 1; therefore, since, for example, upon over-etching of 30%, the in-plane of the interlayer insulating film 2 is reduced by about 0.0 μm to 0.3 μm, the insulating film 4 film-formed by the CVD process in the second process S2 is allowed to intrude into the interlayer insulating film 2 side by about 0.3 μm on the bottom surface of the through hole 6, near the interface between the silicon semiconductor substrate 1 and the interlayer insulating film 2. The reason why the numeric value of the intrusion into the interlayer insulating film 2 side is set to about 0.3 μm is because the intrusion is prevented from reaching the pad electrode 5, and any desired value may be used as long as it is prevented from reaching the pad electrode 5.

The interlayer insulating film 2 is composed of at least one or more kinds of insulating films, and prepared as a combination of an element-separation thermal oxide film, silicon nitride, non-doped silicon glass, BP-doped silicon glass, and low dielectric insulating film, or any of these.

By properly combining the arbitrary embodiments of the aforementioned various embodiments, the effects possessed by the embodiments can be produced.

The method of forming a through electrode and a semiconductor device of the present invention relates to a forming structure of the through electrode in which an electronic circuit including an active element on a first surface of the semiconductor substrate and a conductive layer on a second surface of a semiconductor substrate are electrically connected, and makes it possible to produce the structure at low costs, and also to ensure the reliability of a semiconductor device.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

1. A method for forming a through electrode, in which an interlayer insulating film is formed on a first surface of a semiconductor substrate; an electronic circuit including an active element is disposed on the interlayer insulating film; and an electrode that is connected to the electronic circuit and formed on the first surface thereof, and a conductive layer formed on a second surface of the semiconductor substrate, are connected by using the through electrode, the method comprising:
forming a through hole through the semiconductor substrate, which passes toward the electrode from the second surface to the interlayer insulating film;
forming an insulating film on a side surface and a bottom surface of the through hole as well as on the second surface;
etching the insulating film formed on the bottom surface and the interlayer insulating film on the electrode so that a surface of the electrode on a first surface side is exposed; and
forming a metal layer on each of the second surface of the semiconductor substrate and the side surface and the bottom surface of the through hole so that the through electrode is formed, with the electrode exposed and the metal layer being connected with each other by the through electrode.

2. The method for forming a through electrode according to claim 1, wherein among a thickness A of the insulating film formed on the second surface, a thickness B of the insulating film formed on the bottom surface of the through hole, a thickness C of the interlayer insulating film formed on the first surface, an etching rate D at which the insulating film is removed from the second surface, and an average etching rate E at which the insulating film on the bottom surface of the through hole formed and the thickness C of the interlayer insulating film are etched, the following expression is satisfied.
(B+C)/A<E/D

3. The method for forming a through electrode according to claim 1, wherein upon forming the through hole, a resist mask that covers portions other than a through electrode formation portion on the second surface is disposed on the second surface, and the through hole is formed through the semiconductor substrate corresponding to the through electrode formation portion that is not covered with the resist mask so that the resist mask is then removed from the second surface.

4. The method for forming a through electrode according to claim 1, wherein forming the through hole through the semiconductor substrate and forming the insulating film, further comprising washing.

5. The method for forming a through electrode according to claim 1, wherein etching the insulating film, the insulating film on the bottom surface of the through hole formed and the interlayer insulating film located between the bottom surface of the through hole and the electrode are removed by a dry etching process so that by processing the insulating film on the bottom surface of the through hole and the interlayer insulating film located between the bottom surface of the through hole and the electrode, the through hole is allowed to further extend to an inside of the interlayer insulating film, thereby exposing the electrode on the first surface to the bottom surface of the through hole.

6. The method for forming a through electrode according to claim 1, wherein upon forming the insulating film, any one of processes selected from a group consisting of thermal CVD, plasma CVD, normal-pressure CVD, and TEOSCVD processes is used.

7. The method for forming a through electrode according to claim 5, wherein a dry etching process is used as the etching, and upon processing the insulating film on the bottom surface of the through hole and the interlayer insulating film that is located on the first surface as well as between the bottom surface of the through hole and the electrode, by the dry etching process, a plasma for use in dry etching is generated by using any one of high-density plasma sources selected from a group consisting of inductive coupling plasma, helicon plasma, electronic cyclotron resonance plasma, and VHF plasma sources.

8. The method for forming a through electrode according to claim 5, wherein upon carrying out the dry etching process as the etching, a gas for use in the dry etching to be introduced into a vacuum container for dry etching in which the semiconductor substrate is placed is set to a pressure of 5 Pa or less.

9. A semiconductor device comprising the semiconductor substrate having the through electrode formed by using the method for forming a through electrode described in claim 1.

10. A semiconductor device, in which: an interlayer insulating film is formed on a first surface of a semiconductor substrate; an electronic circuit including an active element is arranged on the interlayer insulating film; and an electrode that is connected to the electronic circuit and formed on a first surface thereof, and a conductive layer formed on the second surface of the semiconductor substrate, are connected by using the through electrode, the device further comprising:
an insulating film that is placed between the through electrode and the semiconductor substrate as well as inside the through hole, so as to insulate between the through electrode and the semiconductor substrate; and
an interlayer insulating film that is placed on the first surface to insulate the electrode and the semiconductor substrate from each other, and is made in contact with the through electrode.
